(19) United States
(12) Patent Application Publication
(10) Pub. No.: US 2025/0105799 A1
(43) Pub. Date: Mar. 27, 2025

(54) Compact Doherty Amplifier Having Improved Video Bandwidth

(71) Applicant: Ampleon Netherlands B.V., Nijmegen (NL)

(72) Inventor: Daniel Maassen, Nijmegen (NL)

(21) Appl. No.: 18/833,283

(22) PCT Filed: Jan. 30, 2023
(86) PCT No.: PCT/NL2023/050038

§ 371 Date: Jul. 25, 2024

(30) Foreign Application Priority Data
Jan. 28, 2022 (NL) 2030764

(51) Int. Cl. H03F 1/56; H03F 1/02; H03F 3/21

(52) U.S. Cl. CPC H03F 1/56; H03F 1/0288; H03F 3/211; H03F 2200/222; H03F 2200/387; H03F 2200/451; H03F 2200/552

(57) ABSTRACT

Example embodiments relate to compact Doherty amplifiers having improved video bandwidth. One example embodiment includes an amplifier. The amplifier includes a package having a substrate. The amplifier also includes at least one amplifier unit arranged in the package. Each amplifier unit includes an input terminal and an output terminal. Each amplifier unit also includes an active semiconductor die on which a high-power transistor is integrated. Additionally, each amplifier unit includes an input matching capacitor and an output matching capacitor. Further, each amplifier unit includes a third inductor connecting an output of the high-power transistor to the output matching capacitor. In addition, each amplifier unit includes a fourth inductor connecting an input of the high-power transistor to the input matching capacitor. Yet further, each amplifier unit includes an output resonance network including a series connection of a first inductor and a first capacitor. Each amplifier unit includes a passive semiconductor die.

### CROSS-REFERENCE TO RELATED APPLICATIONS

The present application is a national stage entry of PCT/NL2023/050038 filed Jan. 30, 2023, which claims priority to NL 2030764 filed Jan. 28, 2022, the contents of each of which are hereby incorporated by reference.

The present invention relates to an amplifier and to a Doherty amplifier comprising the same. More in particular, the present invention relates to a radiofrequency, RF, power amplifier that is configured for outputting power in excess of 1 Watt at a frequency between 0.1 and 60 GHz.

Typically, an RF power amplifier for a mobile telecommunications base station comprises a power amplifier that is based on a Doherty topology. In a Doherty amplifier, a signal to be amplified is first split, by a Doherty splitter, into a main signal and a peak signal. These signals are then amplified by a main amplifier and a peak amplifier, respectively. The main amplifier is typically biased in class AB or B, whereas the peak amplifier is typically biased in class C. Consequently, for low input power, only the main amplifier will amplify signals, whereas at high input powers, both the main and peak amplifiers contribute to the outputted signal.

The signals amplified by the main and peak amplifiers are combined, by a Doherty combiner, into an output signal. Typically, the Doherty combiner comprises an impedance inverter that is configured to introduce load modulation at the output of the main amplifier. More specifically, the impedance seen by the main amplifier at low input power is higher than that seen at high input powers due to the peak amplifier being switched off at low input powers. The impedance inverter can be realized using a quarter wavelength transmission line or the electrical equivalent thereof. The load modulation allows the Doherty amplifier to achieve good efficiencies both at low and high input powers.

Various alternative Doherty configurations are known, such as a parallel Doherty or an inverted Doherty, that differ in the way the impedance inverter is connected. Furthermore, the Doherty splitter typically imparts a phase offset such that the signals amplified by the main and peak amplifiers add in-phase at the output.

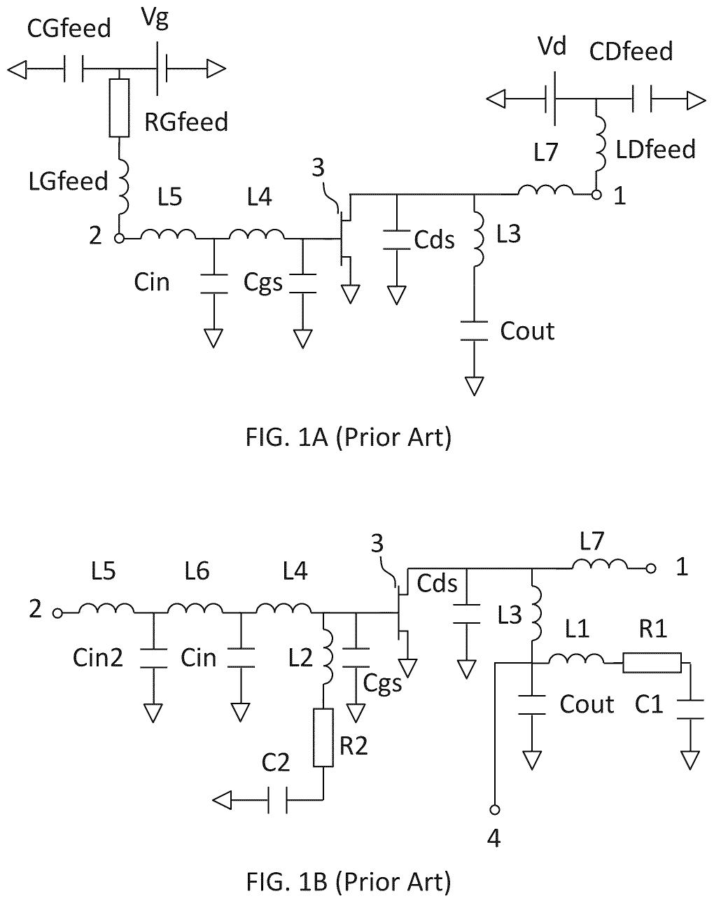

FIGS. 1A and 1B illustrate electrical circuits of amplifiers known in the art. In both figures, an electrical circuit is shown of an amplifier having an output terminal 1 and an input terminal 2. As active component, the amplifiers both comprise a FET 3 having a particular output capacitance Cds and a particular input capacitance Cgs. To mitigate the effect of Cds on the RF performance in the operational frequency range, an output resonance network is provided that comprises a series connection of an inductor L3 and an output matching capacitor Cout. This network is configured such that at or close to the operational frequency of FET 3, the network behaves as an inductor that resonates with Cds. Consequently, the parallel combination of Cds and the output resonance network acts as an open at or close to the operational frequency of FET 3. Furthermore, output matching capacitor Cout prevents a DC path to ground and acts as an RF short in the operational bandwidth of the amplifier.

The drain of FET 3 is further connected using an inductor L7 to output terminal 1. In FIG. 1A, a DC biasing network is shown that is connected to output terminal 1. This network comprises a biasing line formed by an inductor LDfeed by which output terminal 1 is connected to a voltage source Vd. A capacitor CDfeed is provided that provides a short at RF frequencies. Inductor LDfeed is typically realized using a quarter wavelength transmission line. Such line transforms the short at RF frequencies caused by CDfeed to an open at output terminal 1. Similarly, input 2 of the amplifier is connected to a biasing network comprising a bias source Vg, a biasing line formed by an inductor LGfeed that is typically implemented as a quarter wavelength transmission line, and an RF decoupling capacitor CGfeed. Furthermore, an input matching network is formed comprising input matching capacitor Cin, and inductors L5 and L4.

The parasitic capacitances Cgs, Cds resonate at a baseband frequency with the biasing line LGfeed and biasing line LDfeed, respectively, which are arranged outside the package in which FET 3 is realized. The inductance of the biasing lines and therefore the resonance frequency is not free of choice as the length of these lines corresponds to a quarter wavelength at the operational frequency of the amplifier. With increased parasitic in-and output capacitances and/or decreased operational frequencies, the resonance drops down towards the baseband bandwidth of the transistor.

The contribution of the output baseband resonance frequency is widely known in the art. A known solution to address this problem is to push out the baseband resonance introduced by LDfeed and Cds by a resonance circuit comprising an inductor L1, a resistor R1, and a capacitor C1 as shown in FIG. 1B, where it is noted that the biasing networks themselves are not shown in FIG. 1B. By using the resonance circuit, a flat low-ohmic output impedances can be obtained at baseband frequencies keeping the intermodulation products free of resonances.

A similar resonance occurs at the input side of the device by the resonance of the LGfeed and Cgs. At the input side of the device the resonance can be damped externally with RGfeed to an acceptable level. However, it has been found that the strong non-linear behavior of Cgs leads to a modulation of the damped baseband response over the input signal excitation Vgs. This causes strong memory effects leading to an input induced inter-modulation distortion asymmetry between high and low side and challenges linearizability of the power amplifier. FIG. 1B illustrates a known solution to address this problem. More in particular, a further resonance circuit comprising an inductor L2, resistor R2, and capacitor C2, is connected to the gate of FET 3. This network dampens the oscillatory behavior of the impedance at relatively low frequencies that would otherwise reduce the video bandwidth of the amplifier. In addition, FIG. 1B illustrates a two-stage input matching network comprising inductors L4-L6, and capacitors Cin, Cin2, although a single stage input matching network could equally have been used.

In addition to efficiency, the stability of the power amplifier is of importance. Stability is often adversely affected by electromagnetic coupling between the various components of the amplifier, and in particular between components at the input and components at the output.

A continuing demand exists in the art for realizing power amplifiers with the same or improved output power and efficiency but with a smaller footprint. However, decreasing the footprint increases the risk of the amplifier being unstable in at least some operating conditions.

It is an object of the present invention to provide an amplifier that offers a solution to this conflict.

According to the present invention, this object is achieved using the amplifier as defined in claim 1 that comprises a package having a substrate and at least one amplifier unit arranged in the package. Each amplifier unit comprises an input terminal, an output terminal, and an active semiconductor die on which a high-power transistor, such as a field-effect transistor FET, is integrated. The active semiconductor die is mounted on the substrate and has a first edge arranged in between the high-power transistor and the input terminal, and a second edge arranged in between the high-power transistor and the output terminal.

Each amplifier unit further comprises an input matching capacitor and an output matching capacitor, a third inductor connecting an output of the high-power transistor to the output matching capacitor, and a fourth inductor connecting an input of the high-power transistor to the input matching capacitor. Each amplifier unit additionally comprises an output resonance network comprising a series connection of a first inductor and a first capacitor and connected in between ground and the output of the high-power transistor through the third inductor.

According to the present invention, each amplifier unit comprises at least one passive semiconductor die mounted on the substrate in between the active semiconductor die and the input terminal, wherein the input matching capacitor and the first capacitor are integrated on the at least one passive semiconductor die, and wherein the output matching capacitor is integrated on the active semiconductor die closer to the first edge than to the second edge.

The Applicant has found that the abovementioned configuration enables the first capacitor, which is electrically connected near the output of the amplifier, to be arranged closely to components of the input of the amplifier without degrading the stability of the amplifier.

To provide an even improved stability of the amplifier, the third inductor can be electromagnetically coupled to the fourth inductor for at least partially compensating an electromagnetic coupling between the first inductor and the fourth inductor. This coupling may arise due to the close placement of the first capacitor and the input matching capacitor to which the fourth inductor is connected, causing a coupling between the input and output circuitry of the amplifier. The Applicant has found that this coupling can be mitigated by ensuring sufficient electromagnetic coupling between the third and fourth inductors. For example, these inductors can be arranged close to each other and can extend in an at least partially parallel manner or in an at least partially overlapping manner.

To improve compactness of the amplifier, the input matching capacitor and the first capacitor can be integrated on the same passive semiconductor die.

The output resonance network may further comprise a first resistor arranged in series with the first inductor and the first capacitor. The first resistor is preferably integrated on the same passive semiconductor die as the first capacitor and/or is at least partially formed by a resistance of the first capacitor.

The amplifier may further comprise an input resonance network that comprises a series connection of a second inductor and a second capacitor, and that is connected in between the input of the high-power transistor and ground. The input resonance network may further comprise a second resistor arranged in series with the second inductor and the second capacitor, wherein the second resistor is preferably integrated on the same passive semiconductor die as the second capacitor and/or is at least partially formed by a resistance of the second capacitor. Additionally or alternatively, the first capacitor and the second capacitor can be integrated on the same passive semiconductor die.

The first and second resistor may be configured to dampen any resonances occurring in and/or due to the resonance network(s). Alternatively or additionally, the first and/or second resistor can be formed using a thin layer of resistive material deposited on the relevant passive semiconductor die.

The first capacitor and the second capacitor may each comprise a respective non-grounded terminal and a grounded terminal, wherein the grounded terminals of the first and second capacitors are electrically connected and/or integrally connected, and wherein the first capacitor is formed by a first deep trench capacitor and/or wherein the second capacitor is formed by a second deep trench capacitor.

Typically, a deep trench capacitor comprises a plurality of trenches, an inner wall of each trench being covered by a first metal layer. The trenches comprise a dielectric layer arranged in between the first metal layer and a second metal layer.

For realizing the abovementioned first and second capacitors, a deep trench capacitor can be used that further comprises a first interconnect for electrically connecting the second metal layers of a first set of the trenches, and a second interconnect for electrically connecting the second metal layers of a second set of the trenches, the second set excluding the trenches of the first set. In this case, the first interconnect is connected to and/or at least partially forms a non-grounded terminal of the first capacitor, and the second interconnect is connected to and/or at least partially forms a non-grounded terminal of the second capacitor. Furthermore, the semiconductor substrate of the at least one passive semiconductor die may be a conductive substrate allowing an electrical connection between the first metal layer arranged in the trenches and the substrate.

The amplifier unit may further comprise an input conductor through which the input matching capacitor is connected to the input terminal, the input conductor comprising a plurality of input bondwires. In addition, the amplifier unit may further comprise a second input matching capacitor, preferably arranged on the same passive semiconductor die as the input matching capacitor, and a plurality of intermediate bondwires forming an intermediate inductor, wherein the input bondwires electrically connect the input terminal and the second input matching capacitor, and wherein the intermediate bondwires electrically connect the second input matching capacitor and the input matching capacitor.

The input matching capacitor may be formed by a first metal-insulator-metal capacitor, and/or the second input matching capacitor may be formed by a second metal-insulator-metal capacitor, and/or the output matching capacitor may be formed by a third metal-insulator-metal capacitor.

The amplifier unit may comprise an output inductor connecting the output of the high- power transistor to the output terminal. This output inductor may comprise a plurality of output bondwires.

The first inductor may comprise one or more first bondwires electrically connecting the output matching capacitor and the first capacitor. This connection may be a direct connection in which the one or more first bondwires are physically connected to the non-grounded terminal of the first capacitor. Alternatively, the connection can be an indirect connection as a result of the first resistor being arranged in between the one or more first bondwires and the non-grounded terminal of the first capacitor.

Similarly, the second inductor may comprise one or more second bondwires electrically connecting the input of the high-power transistor and the second capacitor. This connection may be a direct connection in which the one or more second bondwires are physically connected to the non-grounded terminal of the second capacitor. Alternatively, the connection can be an indirect connection as a result of the second resistor being arranged in between the one or more second bondwires and the non-grounded terminal of the second capacitor.

The fourth inductor may comprise a plurality of fourth bondwires electrically connecting the input of the high-power transistor and the input matching capacitor. A part of the fourth inductor can be configured to electromagnetically couple with a part of the third inductor for at least partially compensating for an electromagnetic coupling between the one or more first bondwires and the one or more fourth bondwires.

The third inductor may comprise a plurality of third bondwires. In this case, the plurality of fourth bondwires may comprise a first set of fourth bondwires extending between the input matching capacitor and a first bondpad assembly on the active semiconductor die, and a second set of fourth bondwires extending between a second bondpad assembly and a third bondpad assembly. The first bondpad assembly may be integrally formed with and/or electrically connected to the second bondpad assembly, and the first bondpad assembly can be arranged closer to the first edge than the second and third bondpad assemblies. Furthermore, the second bondpad assembly can be arranged closer to the first edge than the third bondpad assembly, and the fourth bondwires of the second set may extend adjacent and substantially parallel to the plurality of third bondwires.

Another manner in which coupling between the fourth bondwires and the third bondwires can be realized is when the fourth bondwires extend between the input matching capacitor and a first bondbar assembly on the active semiconductor die, and when the third bondwires extend between the output of the high-power transistor and a second bondbar assembly. In this case, the second bondbar assembly can be arranged closer to the first edge than the first bondbar assembly.

In both configurations described above, the first bondpad assembly, second bondpad assembly, and/or third bondpad assembly may comprise, independent from each other, a plurality of spaced apart bondpads or one or more bondbars.

An even further manner in which coupling between the fourth bondwires and the third bondwires can be realized is when the third inductor comprises a third coupling part and the fourth inductor a fourth coupling part, wherein the third and fourth coupling parts are integrated on the active semiconductor die as coupled lines. Examples of coupled lines are coupled transmission lines, such as broadside coupled lines or edge coupled lines.

Each amplifier unit may comprise a first video terminal that is electrically connected to the output matching capacitor, preferably using one or more bondwires. Additionally or alternatively, each amplifier unit may comprise a second video terminal that is electrically connected to the second capacitor, preferably using one or more bondwires.

The at least one amplifier unit may comprise a pair of amplifier units of which the input terminals are adjacently arranged and of which the output terminals are adjacently arranged. These amplifier units may or may not be identical in terms of saturated output power, biasing, layout, and the like.

The input matching capacitors of the pair of amplifier units can be electrically connected, for example using one or more bondwires. Similarly, the second input matching capacitors of the pair of amplifier units can be electrically connected, for example using one or more bondwires.

The package may comprise a lead-frame based package, a molded package, a dual flat no leads, or a quad flat no leads, package. The high-power transistor can be a silicon-based laterally diffused metal oxide semiconductor transistor or a gallium nitride based field-effect transistor.

According to a further aspect, the present invention provides a Doherty amplifier comprising a printed circuit board, a main amplifier, and a peak amplifier, both mounted on the printed circuit board. In addition, the Doherty amplifier comprises a Doherty splitter for splitting an input RF signal into a main signal to be fed to the main amplifier and a peak signal to be fed to the peak amplifier. The Doherty amplifier further comprises at least one amplifier as defined above that is mounted on the printed circuit board, wherein the amplifiers units of the at least one amplifier jointly form the main amplifier and/or the peak amplifier. The Doherty amplifier further comprises a Doherty combiner for combining the main signal amplified by the main amplifier and the peak signal amplified by the peak amplifier. The at least one amplifier may comprise a single amplifier of which one amplifier unit forms the main amplifier and of which an other amplifier unit forms the peak amplifier. Hence, in such case, the main and peak amplifiers are realized in the same package.

In so far the at least one amplifier comprises a first video lead, the Doherty amplifier may further comprise a DC decoupling capacitor connected between the first video lead and ground.

Next, the present invention is illustrated in more detail referring to the appended drawings, wherein identical or similar components are referred to using the same reference signs, and wherein:

FIGS. 1A and 1B illustrate electrical circuits of amplifiers known in the art;

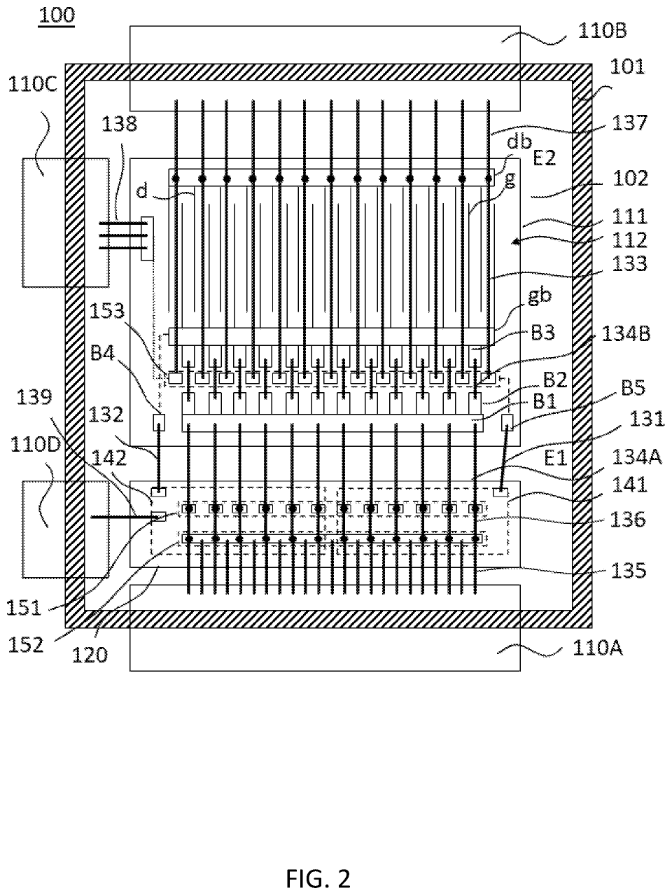

FIG. 2 illustrates an embodiment of an amplifier in accordance with the present invention;

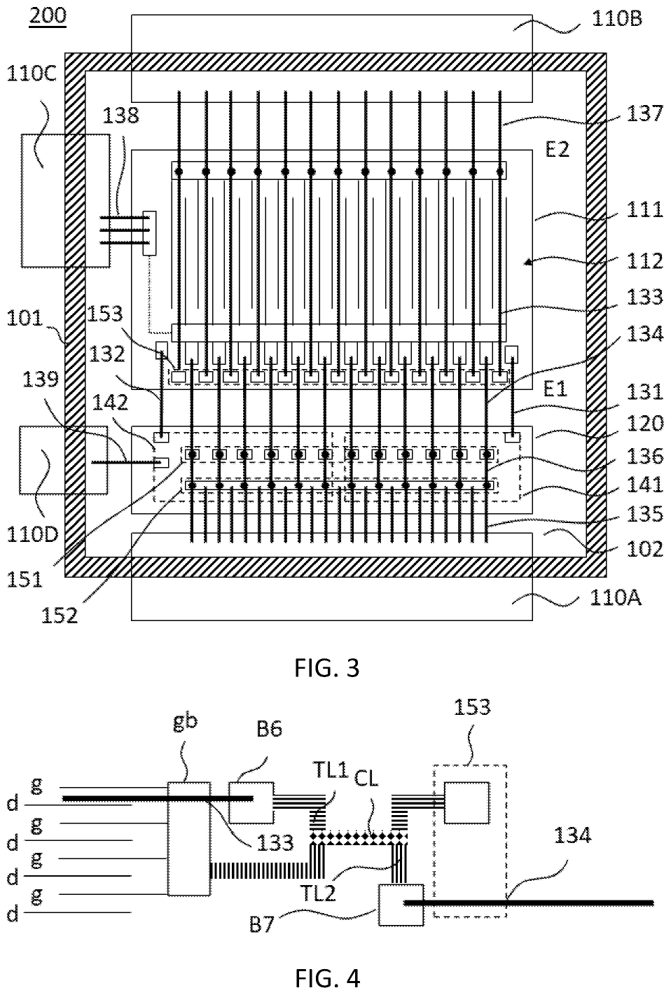

FIG. 3 illustrates a further embodiment of an amplifier in accordance with the present invention;

FIG. 4 illustrates a further option of realizing electromagnetic coupling to be used in an amplifier in accordance with the present invention; and

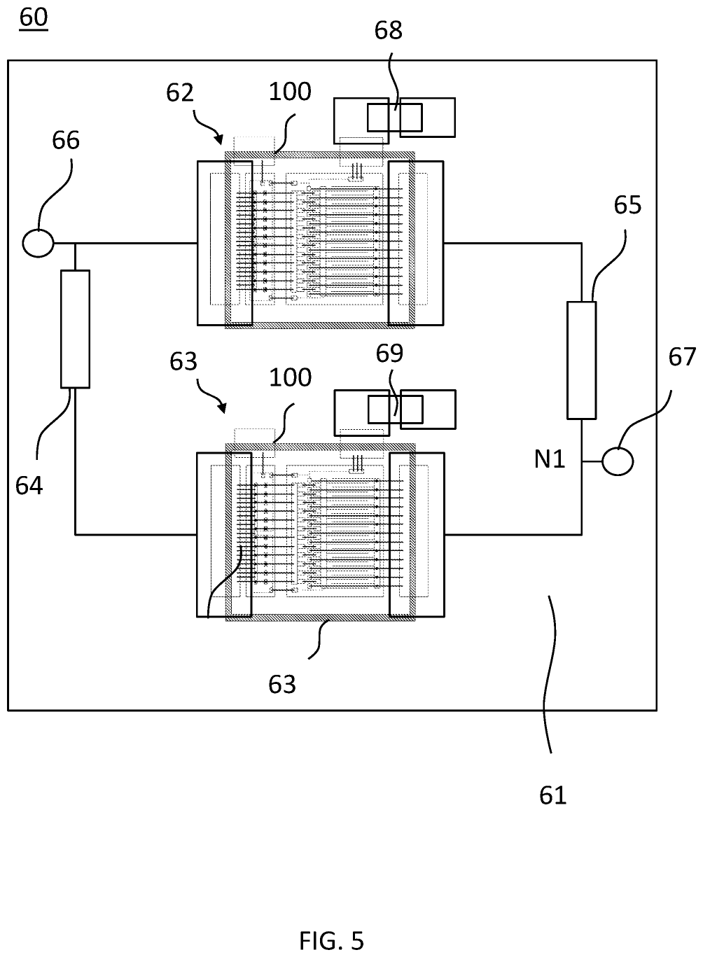

FIG. 5 illustrates an embodiment of a Doherty amplifier in accordance with the present invention.

FIG. 2 illustrates an embodiment of an amplifier 100 in accordance with the present invention of which the operation corresponds to the circuit of FIG. 1B. Amplifier 100 comprises a package 101, which package comprises a heat-conducting substrate 102, such as a copper flange or the like, on which a semiconductor die 111 is mounted. On die 111, a field-effect transistor, FET, 112 is integrated. FET 112 is part of an amplifier unit of amplifier 100. This amplifier unit further comprises an input terminal 110A and an output terminal 110B. Semiconductor die 111 has a first edge E1 arranged in between FET 112 and input terminal 110A, and a second edge E2 arranged in between FET 112 and output terminal 110B.

The amplifier unit further comprises a passive semiconductor die 120 mounted on substrate 102 in between semiconductor die 111 and input terminal 110A. On passive semiconductor die 120, a first metal-insulator-metal capacitor 151 and a second metal-insulator-metal capacitor 152 are integrated. In FIG. 2, a top plate of these capacitors is indicated using dashed rectangles. In addition, bondpads are shown inside these rectangles by which these capacitors are contacted.

On passive semiconductor die 120, a first deep trench capacitor 141 and a second deep trench capacitor 142 are integrated. More in particular, in FIG. 2, the non-grounded terminals of these capacitors are indicated using dashed rectangles, and the grounded terminals are formed by the conductive substrate of passive semiconductor die 120.

On active semiconductor die 111 a third metal-insulator-metal capacitor 153 is integrated of which a top plate is indicated by a dashed rectangle. This capacitor is also contacted using bondpads.

Referring to FIG. 1B, first deep trench capacitor 141 corresponds to C1, second deep trench capacitor 142 to C2, first metal-insulator-metal capacitor 151 to Cin, second metal-insulator-metal capacitor 152 to Cin2, and third metal-insulator-metal capacitor 153 to Cout.

In FIG. 2, a plurality of input bondwires 135 forms inductor L5 and connects input terminal 110A to the non-grounded terminal of second metal-insulator-metal capacitor 152, and a plurality of intermediate bondwires 136 forms inductor L6 and connects the non-grounded terminal of second metal-insulator-metal capacitor 152 to the non-grounded terminal of first metal-insulator-metal capacitor 151.

FET 112 comprises a plurality of gate fingers g and a plurality of drain fingers d. Gate fingers g are interconnected using a gate bar gb that in turn is connected to a third bondpad assembly B3. This latter bondpad assembly is connected to a second bondpad assembly B2 using a plurality of bondwires 134B. In turn, second bondpad assembly B2 is physically connected to first bondpad assembly B1. This latter assembly is connected to the non-grounded terminal of first metal-insulator-capacitor 151 using a plurality of bondwires 134A. The entire connection between gate bar gb and the non-grounded terminal of first metal-insulator-capacitor 151 forms inductor LA.

Drain fingers d are connected to each other by a drain bar db. A plurality of output bondwires 137 forms L7 and connects drain bar db to output terminal 110B. In addition, a plurality of third bondwires 133 forms L3 and connects drain bar db to the non-grounded terminal of the third metal-insulator-metal capacitor 153.

One or more second bondwires 132 partially forms inductor L2 and connects the non- grounded terminal of second deep trench capacitor 142 to one or more bondpads B4 on active semiconductor die 111. Bondpads B4 are/is connected to gate bar gb, as illustrated by the dashed line.

One or more first bondwires 131 partially forms inductor L1 and connects the non-grounded terminal of first deep trench capacitor 141 to one or more bondpads B5 on active semiconductor die 111. Bondpads B5 are/is connected to the non-grounded terminal of third metal-insulator-metal capacitor 153, as illustrated by the dashed line.

As shown, the non-grounded terminal of second deep trench capacitor 142 is connected via one or more bondwires 139 to a second video terminal 110D. Optionally, DC gate biasing can be supplied via this terminal. Similarly, the non-grounded terminal of first deep trench capacitor 141 is connected via one or more bondwires 138 to a first video terminal 110C. Optionally, DC drain biasing can be supplied via this terminal.

Bondwire(s) 131, which partially form(s) an inductor L1, extend(s) in parallel to bondwires 134A, which partially form L4. As bondwire(s) 131 is/are part of the output circuitry and bondwires 134A part of the input circuitry, a risk of instability may exist. This risk can be attributed to the fact that first deep trench capacitor 141, e.g. C1, and first metal-insulator-metal capacitor 151, e.g. Cin, are both arranged on passive semiconductor die 120. To address this concern, an intentional coupling between inductors L4 and L3 is introduced. More in particular, part of inductor L4, namely the part associated with bondwires 134B, couples electromagnetically with third bondwires 133 that form L3. According to the present invention, this coupling is intentional and is intended to at least partially compensate the electromagnetic coupling between L1 and L4.

FIG. 3 illustrates a further embodiment of an amplifier in accordance with the present invention. The FIG. 3 embodiment differs from the FIG. 2 embodiment in that inductor L4 is not formed using two distinct sets of bondwires, e.g. 134A and 134B, but is formed using a single set of bondwires 134 of which a last segment couples with bondwires 133. This can be realized by using a different positioning of third metal-insulator-metal capacitor 153 relative to the bondpads that bondwires 133 are connected to.

FIG. 4 illustrates a further option of realizing electromagnetic coupling to be used in an amplifier in accordance with the present invention. In this figure it is shown that bondwires 133 each land on a bondpad B6 from which a transmission line TL1 extends to the non-ground terminal of third metal-insulator-metal capacitor 153. In addition, bondwires 134 are connected to a bondpad B7 from which a transmission line TL2 extends to gate bar gb. Transmission lines TL1 and TL2 run close to each other, at least locally, to facilitate electromagnetic coupling. In FIG. 3, in the region indicated by a diamond pattern, TL2 extends over TL1 (or vice versa) thereby forming a set of coupled lines CL. Such cross-over can be realized using a multi-layer metal stack in which metal layers are separated by dielectric layers. It should be noted that the present application is not limited to the layout as depicted in FIG. 4. More in particular, the positions of bondpad B6 and third metal-insulator-metal capacitor 153 can be reversed to change the sign of the electromagnetic coupling.

FIG. 5 illustrates an embodiment of a Doherty amplifier 60 in accordance with the present invention. Doherty amplifier 60 comprises a printed circuit board 61 on which two amplifiers 100 are mounted. One amplifier 100 acts as a main amplifier 62 and the other amplifier 100 as peak amplifier 63. An RF signal inputted at input terminal 66 is split by Doherty splitter 64 into a signal that is fed to main amplifier 62 and a signal that is fed to peak amplifier 63. Typically, the RF signal received at input terminal 66 is split evenly and a phase delay is introduced of roughly 90 degrees at the operational frequency of amplifier 60 to the signal that is fed to peak amplifier 63.

First video leads 110C of main amplifier 62 and peak amplifier 63 are each connected to a grounded capacitor 68, 69 for realizing a short at low frequencies at first video leads 110C. Such a connection could additionally or alternatively be realized for second video leads 110D.

The signals amplified by main amplifier 62 and peak amplifier 63 are combined using Doherty combiner 65. This combiner typically comprises a 90 degrees transmission line connected in between combining node NI and the output terminal of main amplifier 62.

Typically, main amplifier 62 is biased in class A/B or class B and peak amplifier 63 in class C. Consequently, at low input power, only main amplifier 62 is active and at high input power, both main amplifier 62 and peak amplifier 63 are active. Combiner 65 ensures that at low input power, main amplifier 62 is presented with a relatively high impedance at its output, whereas at high input power, a relatively low impedance is presented. This so-called load modulation allows high efficiencies to be obtained.

The topology shown in FIG. 5 corresponds to a regular Doherty. The skilled person is aware of different topologies, such as inverted and parallel Doherty. The present invention is equally applicable to such topologies. Furthermore, an additional impedance matching stage and phase offset line may be arranged in between the output terminal of main amplifier 62 and Doherty combiner. Similarly, an additional impedance matching stage and phase offset line may be arranged in between the output terminal of main amplifier 63 a combining node N1.

In the above, the present invention has been explained using detailed embodiments thereof. However, various modifications of these embodiments are possible without departing from the scope of the present invention, which is defined by the appended claims and their equivalents.

1. An amplifier comprising:
a package having a substrate; and
at least one amplifier unit arranged in the package, each amplifier unit comprising:
an input terminal;
an output terminal;
an active semiconductor die on which a high-power transistor, is integrated, wherein the active semiconductor die is mounted on the substrate and has a first edge arranged in between the high-power transistor and the input terminal, and a second edge arranged in between the high-power transistor and the output terminal;
an input matching capacitor;
an output matching capacitor;
a third inductor connecting an output of the high-power transistor to the output matching capacitor;
a fourth inductor connecting an input of the high-power transistor to the input matching capacitor; and
an output resonance network comprising a series connection of a first inductor and a first capacitor and connected in between ground and the output of the high-power transistor through the third inductor,
wherein each amplifier unit comprises at least one passive semiconductor die mounted on the substrate in between the active semiconductor die and the input terminal, wherein the input matching capacitor and the first capacitor are integrated on the at least one passive semiconductor die, and wherein the output matching capacitor is integrated on the active semiconductor die closer to the first edge than to the second edge.

2. The amplifier according to claim 1, wherein the third inductor is electromagnetically coupled to the fourth inductor for at least partially compensating an electromagnetic coupling between the first inductor and the fourth inductor.

3. The amplifier according to claim 1, wherein the input matching capacitor and the first capacitor are integrated on the same passive semiconductor die.

4. The amplifier according to claim 1, wherein the output resonance network further comprises a first resistor arranged in series with the first inductor and the first capacitor, and wherein the first resistor is integrated on the same passive semiconductor die as the first capacitor or is at least partially formed by a resistance of the first capacitor.

5. The amplifier according to claim 1, further comprising an input resonance network comprising a series connection of a second inductor and a second capacitor and connected in between the input of the high-power transistor and ground,
wherein the input resonance network further comprises a second resistor arranged in series with the second inductor and the second capacitor,
wherein the second resistor is integrated on the same passive semiconductor die as the second capacitor or is at least partially formed by a resistance of the second capacitor,
wherein the first capacitor and the second capacitor are integrated on the same passive semiconductor die,
wherein the first capacitor and the second capacitor each comprise a respective non- grounded terminal and a grounded terminal,
wherein the grounded terminals of the first capacitor and the second capacitor are electrically connected or integrally connected, and
wherein the first capacitor is formed by a first deep trench capacitor or the second capacitor is formed by a second deep trench capacitor.

6. (canceled)

7. (canceled)

8. (canceled)

9. The amplifier according to claim 1,
wherein the amplifier unit further comprises an input conductor through which the input matching capacitor is connected to the input terminal,
wherein the input conductor comprises a plurality of input bondwires,
wherein the amplifier unit further comprises:
a second input matching capacitor arranged on the same passive semiconductor die as the input matching capacitor; and
a plurality of intermediate bondwires forming an intermediate inductor,
wherein the input bondwires electrically connect the input terminal and the second input matching capacitor, and
wherein the intermediate bondwires electrically connect the second input matching capacitor and the input matching capacitor

10. (canceled)

11. The amplifier according to claim 9, wherein:
the input matching capacitor is formed by a first metal-insulator-metal capacitor;
the second input matching capacitor is formed by a second metal-insulator-metal capacitor; or
the output matching capacitor is formed by a third metal-insulator-metal capacitor.

12. The amplifier according to claim 1, wherein the amplifier unit comprises an output inductor connecting the output of the high-power transistor to the output terminal, and wherein the output inductor comprises a plurality of output bondwires.

13. The amplifier according to claim 1,
wherein the first inductor comprises one or more first bondwires electrically connecting the output matching capacitor and the first capacitor,
wherein the fourth inductor comprises a plurality of fourth bondwires electrically connecting the input of the high-power transistor and the input matching capacitor,
wherein a part of the fourth inductor is configured to electromagnetically couple with a part of the third inductor for at least partially compensating for an electromagnetic coupling between the one or more first bondwires and the one or more fourth bondwires, and
wherein the third inductor comprises a plurality of third bondwires.

14. (canceled)

15. (canceled)

16. The amplifier according to claim 13, wherein the plurality of fourth bondwires comprises:
a first set of fourth bondwires extending between the input matching capacitor and a first bondpad assembly on the active semiconductor die; and
a second set of fourth bondwires extending between a second bondpad assembly and a third bondpad assembly,
wherein the first bondpad assembly is integrally formed with or electrically connected to the second bondpad assembly,
wherein the first bondpad assembly is arranged closer to the first edge than the second bondpad assembly and the third bondpad assembly,
wherein the second bondpad assembly is arranged closer to the first edge than the third bondpad assembly, and
wherein the fourth bondwires of the second set extend adjacent and substantially parallel to the plurality of third bondwires.

17. The amplifier according to claim 13, wherein the fourth bondwires extend between the input matching capacitor and a first bondbar assembly on the active semiconductor die, and wherein the third bondwires extend between the output of the high-power transistor and a second bondbar assembly, and wherein the second bondbar assembly is arranged closer to the first edge than the first bondbar assembly.

18. The amplifier according to claim 16, wherein the first bondpad assembly, the second bondpad assembly, or the third bondpad assembly comprise, independent from each other, a plurality of spaced apart bondpads or one or more bondbars.

19. The amplifier according to claim 13, wherein the third inductor comprises a third coupling part, wherein the fourth inductor comprises a fourth coupling part, and wherein the third coupling part and the fourth coupling part are integrated on the active semiconductor die as coupled lines.

20. The amplifier according to claim 1, wherein each amplifier unit comprises a first video terminal that is electrically connected to the output matching capacitor using one or more bondwires.

21. The amplifier according to claim 1, wherein each amplifier unit comprises a second video terminal that is electrically connected to the second capacitor using one or more bondwires.

22. The amplifier according to claim 9, wherein the at least one amplifier unit comprises a pair of amplifier units of which the input terminals are adjacently arranged and of which the output terminals are adjacently arranged,
wherein the input matching capacitors of the pair of amplifier units are electrically connected, and
wherein the second input matching capacitors of the pair of amplifier units are electrically connected.

23. (canceled)

24. (canceled)

25. The amplifier according to claim 1, wherein the package comprises a lead-frame based package, a molded package, a dual flat no leads package, or a quad flat no leads package.

26. The amplifier according to claim 1, wherein the high-power transistor is a silicon-based laterally diffused metal oxide semiconductor transistor or a gallium nitride-based field-effect transistor.

27. A Doherty amplifier, comprising:
a printed circuit board;
a main amplifier and a peak amplifier both mounted on the printed circuit board;
a Doherty splitter for splitting an input RF signal into a main signal to be fed to the main amplifier and a peak signal to be fed to the peak amplifier;
at least one amplifier according to claim 1 mounted on the printed circuit board, wherein the amplifiers units of the at least one amplifier form the main amplifier or the peak amplifier; and
a Doherty combiner for combining the main signal amplified by the main amplifier and the peak signal amplified by the peak amplifier.

28. The Doherty amplifier according to claim 27, wherein the at least one amplifier comprises one amplifier unit that forms the main amplifier and an other amplifier unit that forms the peak amplifier,
wherein each amplifier unit comprises a first video terminal that is electrically connected to the output matching capacitor using one or more bondwires, and
wherein the Doherty amplifier further comprises a DC decoupling capacitor connected between the first video terminal and ground.

29. (canceled)
